(19) United States
(12) Patent Application Publication
(10) Pub. No.: US 2025/0027818 A1
(43) Pub. Date: Jan. 23, 2025

(54) SENSOR, IMAGING DEVICE AND ELECTRONIC DEVICE

(71) Applicant: SONY SEMICONDUCTOR SOLUTIONS CORPORATION, KANAGAWA (JP)

(72) Inventor: YOSHIHIRO ANDO, KANAGAWA (JP)

(21) Appl. No.: 18/714,101

(22) PCT Filed: Dec. 6, 2021
(86) PCT No.: PCT/JP2021/044734

§ 371 Date: May 29, 2024

(51) Int. Cl. G01J 5/12; G01J 5/00; G01J 5/02; G01J 5/08; H01L 27/146

(52) U.S. Cl. CPC G01J 5/12; G01J 5/0225; G01J 5/0815; G01J 2005/0077; H01L 27/14669

(57) ABSTRACT

A sensor according to an embodiment of the present disclosure includes a substrate, a diaphragm including a light absorbing film disposed with a cavity interposed between the light absorbing film and the substrate, a beam portion that supports the diaphragm on the substrate, and a temperature sensing element that detects a temperature change of the light absorbing film. The light absorbing film contains a fibrous material or a sheet-like material that absorbs terahertz waves or infrared rays. The mean value of angles formed by a direction of the fibrous material or a planar direction of a sheet and a direction parallel to the substrate is 45° or less at least in a part of a region of the light absorbing film.

### TECHNICAL FIELD

The present disclosure relates to a sensor, an imaging device, and an electronic device.

### BACKGROUND ART

Sensors for detecting a terahertz wave, an electromagnetic wave at a frequency of about 0.1 to 10 THz, include a sensor having a thermal separation structure. In a thermal separation structure, a light absorbing film that absorbs an electromagnetic wave and a temperature sensing element that detects a temperature change of the light absorbing film are supported while floating from a substrate. The thermal separation structure allows a sensor to have high sensitivity while being connected to a reading circuit.

### CITATION LIST

### Patent Literature

### [PTL 1]

JP 2012-2603A

### [PTL 2]

WO 2018/159638

### SUMMARY

### Technical Problem

In a sensor having the thermal separation structure, if a light absorbing film has poor heat transfer characteristics, it takes a lot of time to transfer heat generated in the light absorbing film to a temperature detecting unit because of the absorption of terahertz waves. Thus, the response speed of the sensor decreases. Generally, the pixel size of an imaging device is often set according to a wavelength of detection in view of balance between sensitivity and a resolution. For example, if a sensor detects 1 THz (wavelength of 300 um) with a pixel size of 300 um, the sensor has a larger pixel size than a conventional infrared sensor. Since the light absorbing film has a large area, the influence of the heat transfer characteristics of the light absorbing film also increases.

The present disclosure provides a sensor, an imaging device, and an electronic device with high sensitivity and excellent responsivity.

### Solution to Problem

A sensor according to an embodiment of the present disclosure includes a substrate, a diaphragm including a light absorbing film disposed with a cavity interposed between the light absorbing film and the substrate, a beam portion that supports the diaphragm on the substrate, and a temperature sensing element that detects a temperature change of the light absorbing film. The light absorbing film contains a fibrous material or sheet-like material that absorbs terahertz waves or infrared rays. The mean value of angles formed by the direction of the fibrous material or the planar direction of a sheet and a direction parallel to the substrate is 45° or less at least in a part of the region of the light absorbing film.

Another sensor according to an embodiment of the present disclosure includes a substrate, a diaphragm including a light absorbing film disposed with a cavity interposed between the light absorbing film and the substrate, a beam portion that supports the diaphragm on the substrate, and a temperature sensing element that detects a temperature change of the light absorbing film. The light absorbing film contains a material that absorbs terahertz waves or infrared rays. Thermal conductivity in a direction parallel to the substrate is higher than thermal conductivity in a direction perpendicular to the substrate at least in a part of the region of the light absorbing film.

Still another sensor according to an embodiment of the present disclosure includes a substrate, a diaphragm including a light absorbing film disposed with a cavity interposed between the light absorbing film and the substrate, a beam portion that supports the diaphragm on the substrate, and a temperature sensing element that detects a temperature change of the light absorbing film. The light absorbing film contains a material that absorbs terahertz waves or infrared rays. The light absorbing film has an opening, the opening having a diameter set at a half or less of a wavelength of light to be detected.

Wherein when the light absorbing film is viewed from a light receiving surface that receives the terahertz waves or the infrared rays, the fibrous material may be oriented in one direction.

When the light absorbing film is viewed from the light receiving surface that receives the terahertz waves or the infrared rays, the fibrous material may be randomly oriented.

The light absorbing film may be a laminated film of layers containing the fibrous material oriented in one direction, the layers having different fiber directions in the laminated film.

The diaphragm may further include an insulating film provided between the light absorbing film and the temperature sensing element, and

the light absorbing film may be provided inside of the insulating film.

The light absorbing film may be a fibrous or sheet-like and porous film.

The temperature sensing element may also act as a beam portion.

The diaphragm may further include an insulating film provided under the light absorbing film, and

the insulating film in contact with the temperature sensing element may have one end formed in a forward tapered shape.

The sensor may further include a reflective film that is provided on the underside of the diaphragm or the front side of the substrate opposed to the diaphragm with the cavity interposed between the substrate and the diaphragm, the reflective film reflecting at least the terahertz waves or the infrared rays.

The temperature sensing element may be connected via a contact via and a wiring to a reading circuit provided on the substrate.

In an imaging device according to an embodiment of the present disclosure, one of the sensors is arranged with a two-dimensional array.

An electronic device according to an embodiment of the present disclosure includes the imaging device.

### BRIEF DESCRIPTION OF DRAWINGS

FIG. 1A is a plan view of a sensor according to a first embodiment.

FIG. 1B is a cross-sectional view taken along cutting line A-A in FIG. 1A.

FIG. 2A is an enlarged plan view of a light absorbing film.

FIG. 2B is an enlarged cross-sectional view of the light absorbing film.

FIG. 3A illustrates an example of orientation of a fibrous material in the light absorbing film in a planar direction.

FIG. 3B illustrates another example of orientation of the fibrous material in the light absorbing film in the planar direction.

FIG. 3C illustrates still another example of orientation of the fibrous material in the light absorbing film in the planar direction.

FIG. 4 is a cross-sectional view illustrating a sensor according to a second embodiment.

FIG. 5 is a cross-sectional view illustrating a sensor according to a modification example of the second embodiment.

FIG. 6A is a plan view of a sensor according to a third embodiment.

FIG. 6B is a cross-sectional view taken along cutting line A-A in FIG. 6A.

FIG. 7 is a cross-sectional view of a sensor according to a fourth embodiment.

FIG. 8 is a cross-sectional view of a sensor according to a fifth embodiment.

FIG. 9 is a cross-sectional view of a sensor according to a sixth embodiment.

FIG. 10 is a cross-sectional view of a sensor according to a seventh embodiment.

FIG. 11 is a cross-sectional view of a sensor according to an eighth embodiment.

FIG. 12A is a cross-sectional view illustrating the step of forming a wiring layer.

FIG. 12B is a cross-sectional view illustrating the step of forming the wiring layer.

FIG. 12C is a cross-sectional view illustrating the step of forming an insulating film, contact vias, and temperature sensing elements.

FIG. 12D is a cross-sectional view illustrating the step of forming a light absorbing film and the insulating film.

FIG. 13 is a cross-sectional view of a sensor according to a ninth embodiment.

FIG. 14A is a cross-sectional view illustrating the step of forming an insulating film and temperature sensing elements.

FIG. 14B is a cross-sectional view illustrating the step of forming the insulating film, contact vias, wirings, a reflective film, and an etching stop film.

FIG. 14C is a cross-sectional view illustrating the step of forming the insulating film, the contact vias, and electrode pads.

FIG. 14D is a cross-sectional view illustrating the step of forming a wiring layer.

FIG. 14E is a cross-sectional view illustrating the step of joining a circuit board and a treated substrate.

FIG. 14F is a cross-sectional view illustrating the step of removing the treated substrate.

FIG. 14G is a cross-sectional view illustrating the step of forming a light absorbing film.

FIG. 15 is a block diagram illustrating the configuration of an imaging device according to a tenth embodiment.

FIG. 16 is a plan view of a pixel array part.

FIG. 17A is a circuit diagram illustrating a reading circuit of a voltage reading system.

FIG. 17B is a circuit diagram illustrating a reading circuit of a CTIA system.

FIG. 18 is a block diagram illustrating a configuration example of an electronic device according to an eleventh embodiment.

FIG. 19 is a block diagram illustrating an example of a schematic configuration of a vehicle control system.

FIG. 20 is an explanatory drawing illustrating an example of installation positions of a vehicle outside information detection unit and imaging units.

### DESCRIPTION OF EMBODIMENTS

### First Embodiment

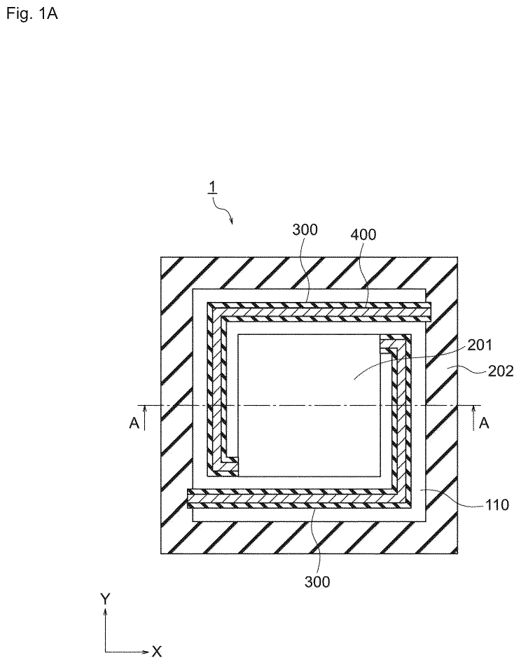

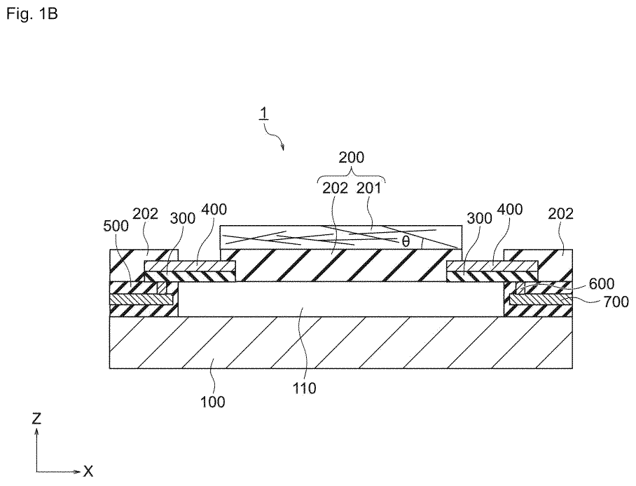

FIG. 1A is a plan view of a sensor according to a first embodiment. FIG. 1B is a cross-sectional view taken along cutting line A-A in FIG. 1A.

As illustrated in FIGS. 1A and 1B, a sensor 1 according to the present embodiment includes a circuit board 100, a diaphragm 200, beam portions 300, temperature sensing elements 400, an insulating film 500, contact vias 600, and wirings 700. The sensor 1 according to the present embodiment is a thermopile sensor. The technique of the present disclosure is also applicable to a bolometer type, a pyroelectric type, a diode type, and other types of sensors. The constituent elements of the sensor 1, for example, the circuit board 100, the diaphragm 200, the beam portions 300, the temperature sensing elements 400, and the insulating film 500 may be made of a single material or a composite material or a plurality of materials in a laminated manner.

The circuit board 100 can be formed by using, for example, a silicon substrate or a glass substrate. On the circuit board 100, a reading circuit (not illustrated) is formed to read a subject detected value of the temperature sensing element 400.

The diaphragm 200 acts as a light receiving unit that detects electromagnetic waves or infrared rays in a far infrared region having a terahertz wave of, for example, about 0.1 THz to 10 THz. The diaphragm 200 includes a light absorbing film 201 and an insulating film 202. The diaphragm 200 is disposed separately from the circuit board 100 with a cavity 110 and the insulating film 202 interposed therebetween. The light absorbing film 201 contains a fibrous or sheet-like material that absorbs electromagnetic waves or infrared rays in a far infrared region having a terahertz wave of, for example, about 0.1 THz to 10 THz. As a fibrous material, for example, a graphene nanoribbon, a carbon fiber, a carbon nanotube (CNT), or a metallic nanowire is applicable. As a sheet material, graphene or the like is applicable. The insulating film 202 electrically isolates the light absorbing film 201 and the temperature sensing elements 400. The insulating film 202 can be formed using, for example, silicon nitride (SiNₓ), silicon oxide (SiOₓ), or aluminum oxide (AlOₓ).

The beam portions 300 extend from the insulating film 500 to support the diaphragm 200. The beam portions 300 can be formed using, for example, SiNₓ, SiOₓ, or AlOₓ. In the present embodiment, as illustrated in FIG. 1A, the two beam portions 300 hold both ends of the diaphragm 200 in the support form. However, the number of beam portions 300 and the support form are not particularly limited if the cavity 110 can be secured between the circuit board 100 and the diaphragm 200, that is, the diaphragm 200 can be continuously floated from the circuit board 100.

The temperature sensing element 400 is provided on the beam portion 300. Alternatively, the temperature sensing element 400 may be embedded in the beam portion 300. The temperature sensing element 400 converts a temperature difference between the light absorbing film 201 and a portion around the light absorbing film 201 into a voltage and outputs the voltage. The temperature sensing element 400 can be formed using polysilicon (Poly-Si), thermoelectric materials such as silicon germanium (SiGe) and bismuth tellurium (Bi₂Te₃), amorphous silicon (αSi), a bolometer material such as vanadium oxide (VOx), or a pyroelectric material.

The insulating film 500 is formed as a sacrificial film to form the cavity 110 between the circuit board 100 and the diaphragm 200. For example, the insulating film 500 can be formed using SiOₓ.

The contact vias 600 and the wirings 700 are provided in the insulating film 500. The contact vias 600 and the wirings 700 connect the temperature sensing elements 400 and the reading circuit formed in the circuit board 100. The contact vias 600 and the wirings 700 can be formed using, for example, metallic materials such as copper.

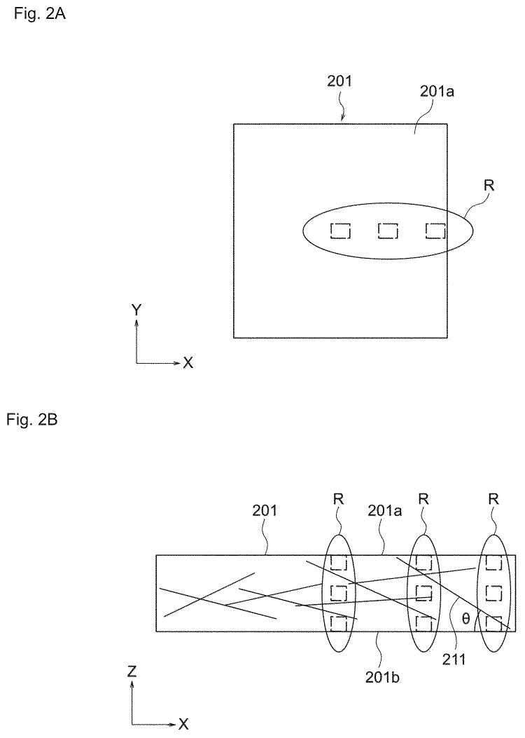

FIG. 2A is an enlarged plan view of the light absorbing film 201. FIG. 2B is an enlarged cross-sectional view of the light absorbing film 201. The light absorbing film 201 in FIG. 2B contains a plurality of pieces of fibrous material 211. In FIG. 2A, the fibrous material 211 is omitted. In the present embodiment, in at least one of a plurality of analysis regions R in a cross section in the thickness direction (Z direction in FIG. 2B) of the light absorbing film 201, the number of pieces of fibrous material 211 having an angle θ of 45° or less is larger than the number of pieces of fibrous material 211 having an angle θ larger than 45°, the angle θ being formed by the direction of the fibrous material 211 and the a direction parallel to the circuit board 100 (X direction in FIG. 2B). In other words, the mean value of the angles θ in the light absorbing film 201 is 45° or less. If the light absorbing film 201 contains a sheet-like material, the mean value of angles formed by the planar direction of a sheet planar direction and a direction parallel to the circuit board 100 is 45° or less.

As illustrated in FIGS. 2A and 2B, for example, the plurality of analysis regions R can be determined around a light receiving surface 201a, at the center of a cross section, and around an underside 201b opposite from the light receiving surface 201a in the thickness direction. Furthermore, the analysis regions R can be determined around the central portion, an intermediate portion, and an end of the light receiving surface in the planar direction (X direction in FIG. 2B).

The direction of the fibrous material 211 in the analysis regions R can be analyzed by observation under, for example, a scanning electron microscope (SEM) or a transmission electron microscope (TEM). For example, if the fibrous material 211 has a diameter on the order of nanometers, the direction of the fibrous material 211 can be confirmed by observation under a TEM set with a magnification of about 100 kx to 400 kx. However, the method for analyzing the orientation of the light absorbing film 201 is not limited to the foregoing method. Any method may be used instead.

If the light absorbing film 201 is an aggregate of a fibrous material, thermal conductivity in a fiber direction is higher than thermal conductivity between fibers. Thus, the more fibers oriented substantially in parallel with the circuit board 100, the higher the thermal conductivity in the planar direction of the light absorbing film 201. This can improve a response speed. Furthermore, in the light absorbing film 201, a fibrous material oriented horizontally with respect to the circuit board 100 can achieve higher mechanical strength to warpage than vertically oriented fibrous materials.

Regardless of whether the component of the light absorbing film 201 is a fibrous material or a sheet-like material, if the light absorbing film 201 has anisotropy of thermal conductivity, the effect of improving the response speed can be obtained as described above when thermal conductivity in a direction (X direction, Y direction) parallel to the circuit board 100 exceeds thermal conductivity in a direction (Z direction) vertical to the circuit board 100 at least in a part of the region of the light absorbing film 201.

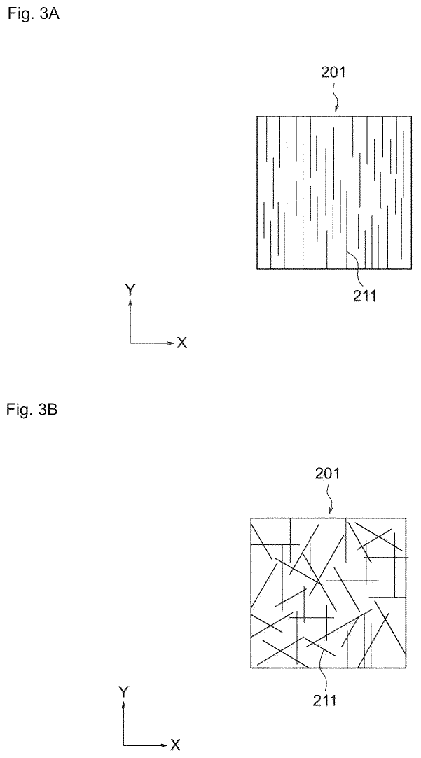

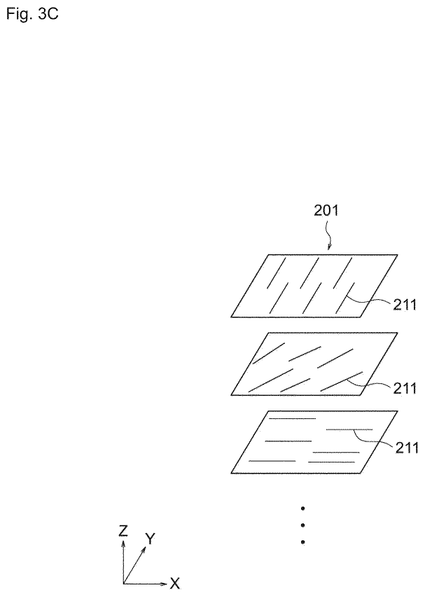

FIGS. 3A to 3C illustrate examples of orientation of the fibrous material 211 in the light absorbing film 201 in the planar direction.

When the light absorbing film 201 in FIG. 3A is viewed from the light receiving surface 201a, the fibrous material 211 is oriented in one direction (Y direction in FIG. 3A). In this case, the sensitivity of the light absorbing film 201 is high relative to electromagnetic waves having electric field oscillations in the fiber direction, and thus the sensor 1 is suitable for a polarization sensor.

When the light absorbing film 201 in FIG. 3B is viewed from the light receiving surface 201a, the fibrous material 211 is randomly oriented. In this case, the sensitivity of the light absorbing film 201 is high relative to electromagnetic waves having electric field oscillations in the fiber direction, and thus the sensor 1 is suitable for a polarization-independent sensor.

The light absorbing film 201 in FIG. 3C is a laminated film of layers containing the fibrous material 211 oriented in one direction. Thus, the light absorbing film 201 has sensitivity to polarization in two or more directions. Moreover, in the light absorbing film 201, the layers have different fiber directions. Thus, the light absorbing film 201 also acts as a polarization-independent sensor.

In the sensor 1 configured thus, the light absorbing film 201 generates heat when absorbing terahertz waves. Hence, when the temperature of the diaphragm 200 increased, infrared rays are radiated from the diaphragm 200 according to the temperature. The temperature sensing element 400 converts the temperature into a voltage and outputs the voltage. At this point, a voltage corresponding to the amount of temperature increase of the diaphragm 200 is output from the temperature sensing element 400.

The sensor 1 according to the present embodiment has a thermal separation structure in which the light absorbing film 201 and the temperature sensing elements 400 are floated from the circuit board 100. Moreover, for the light absorbing film 201, a fibrous material such as a carbon nanotube is used, in which the absorptivity of terahertz waves is high. Thus, the light absorbing film 201 can absorb terahertz waves with high sensitivity.

In a cross-section of the light absorbing film 201, the fibrous material 211 is mostly oriented at 45° or less close to a horizontal direction parallel to the circuit board 100. Therefore, heat quickly diffuses in the light absorbing film 201. This can shorten the time required to transmit heat generated by absorbing terahertz waves in the light absorbing film 201, to the temperature sensing element 400.

Thus, according to the present embodiment, the sensor having high sensitivity and a high response speed can be provided for terahertz waves or infrared rays.

### Second Embodiment

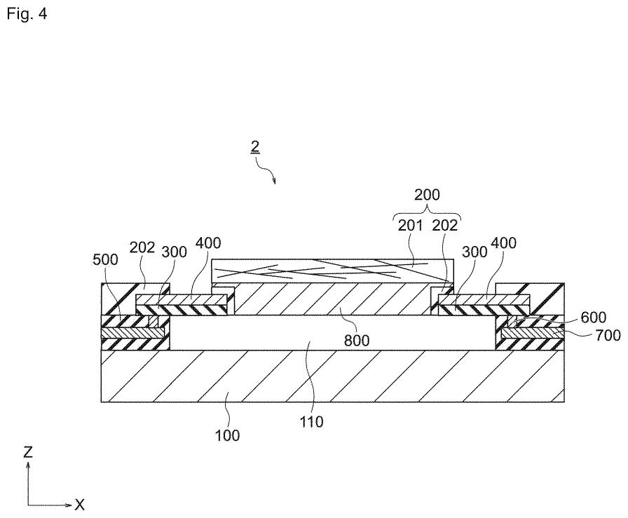

FIG. 4 is a cross-sectional view illustrating a sensor according to a second embodiment. The same constituent elements as those of the first embodiment are indicated by the same reference numerals, and detailed descriptions thereof are omitted.

In a sensor 2 illustrated in FIG. 4, a reflective film 800 is provided on the underside of a light absorbing film 201. The reflective film 800 reflects terahertz waves and infrared rays that have passed through the light absorbing film 201 without being absorbed. The reflective film 800 is desirably made of a material having high reflectivity to terahertz waves and infrared rays. The reflective film 800 can be formed using, for example, metallic materials such as gold (Au), platinum (Pt), aluminum (Al), and tungsten (W).

In the present embodiment, for example, when the light absorbing film 201 generates heat by absorbing terahertz waves, the temperature of the light absorbing film 201 increases, and infrared rays are radiated according to the temperature. In this case, if a material having high reflectivity to infrared rays is mounted as the reflective film 800 on the underside of the light absorbing film 201, infrared rays radiated from the light absorbing film 201 are reflected and reabsorbed. As a result, the temperature loss of a diaphragm 200 decreases, thereby increasing the amount of temperature increase per unit amount of incident light. Therefore, the sensitivity can be further improved.

Moreover, in the present embodiment, if the reflective film 800 can reflect terahertz waves as well, the optical path length of terahertz waves that pass through the light absorbing film 201 is doubled. As a result, the absorbed amount of terahertz waves increases and thus the sensitivity improves also in this case.

Thus, according to the present embodiment, both of a response speed and sensitivity for detection of terahertz waves can be improved.

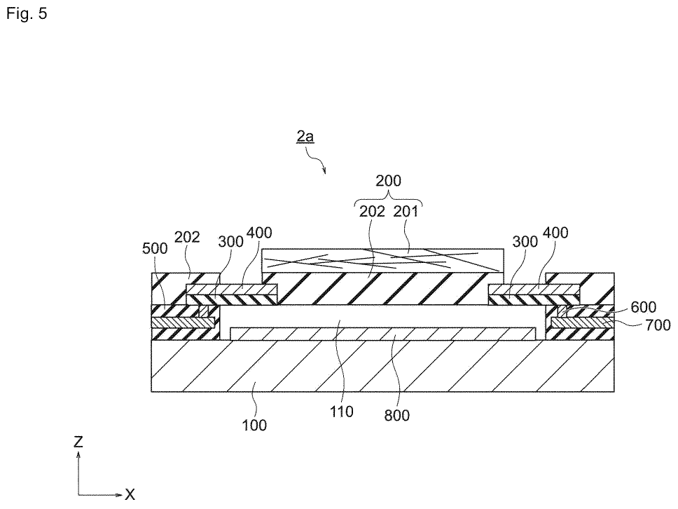

FIG. 5 is a cross-sectional view illustrating a sensor according to a modification example of the second embodiment. In a sensor 2b illustrated in FIG. 5, the reflective film 800 is provided on the front side of a circuit board 100 opposed to the diaphragm 200 with a cavity 110 interposed between the circuit board 100 and the diaphragm 200.

If the reflective film 800 is formed using a metallic material in the second embodiment, the thermal capacity of a metal is relatively large. Hence, as in the present modification example, the reflective film 800 is disposed separately from the diaphragm 200, thereby suppressing the thermal capacity. As a result, a decrease in response speed can be avoided. The reflective film 800 of the present modification example is opposed to the light absorbing film 201 with the cavity 110 interposed therebetween. Thus, terahertz waves and infrared rays that have been transmitted through the light absorbing film 201 pass through the cavity 110 and are reabsorbed after being reflected by the reflective film 800. Therefore, also in the modification example, the sensitivity can be improved while increasing the response speed.

### Third Embodiment

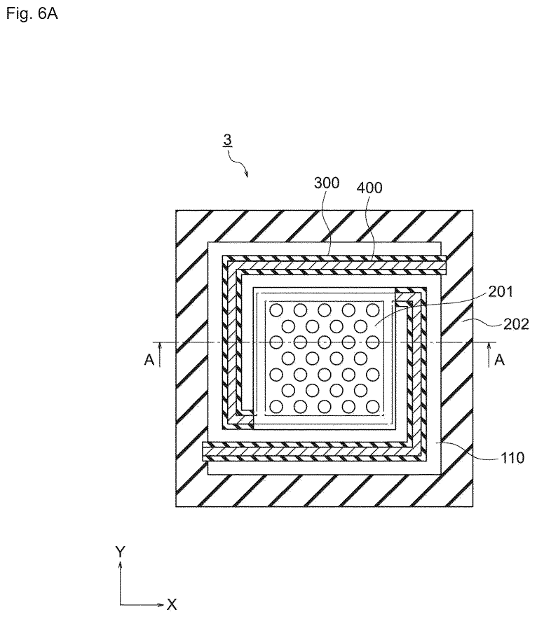

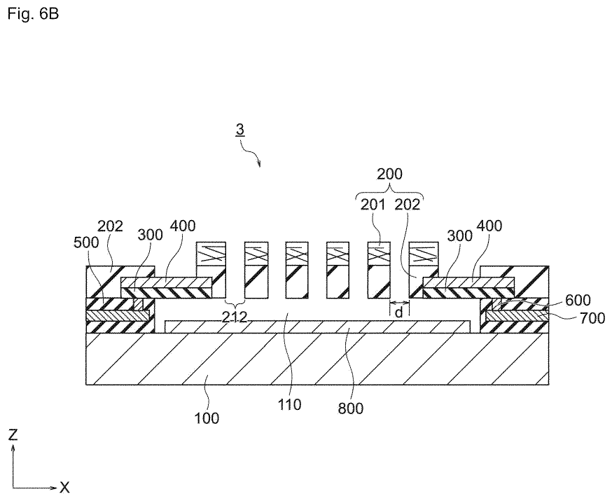

FIG. 6A is a plan view illustrating a sensor according to a third embodiment. FIG. 6B is a cross-sectional view taken along cutting line A-A in FIG. 6A. Hereinafter, different configurations from those of the sensor 2a in FIG. 5 will be mainly described, and descriptions of similar configurations are omitted.

Openings 212 are formed on a diaphragm 200 of a sensor 3 according to the present embodiment. The openings 212 are cavities penetrating a light absorbing film 201 and an insulating film 202 in a thickness direction Z.

The sensor 3 is desirably sized according to the wavelength of a terahertz wave (about 30 um to 1 mm). A larger pixel size leads to the difficulty in forming the openings 212 by etching a part of an insulating film 500 as a sacrificial layer to be formed under the diaphragm 200. The openings 212 act as etching holes during etching on a part of the insulating film 500. Furthermore, the thermal capacity of the diaphragm 200 is reduced, also achieving the effect of improving a response speed.

However, it is assumed that the provision of the openings 212 reduces the absorptivity of terahertz waves according to a diameter d of the opening and results in lower sensitivity. Thus, the diameter d is set sufficiently smaller than a target wavelength detected by the sensor 3, so that electromagnetic waves can be blocked and the absorptivity can be kept. For example, the diameter d is desirably set at a half or less of the target wavelength detected by the sensor 3. In this case, the etching holes can be formed while minimizing a reduction in sensitivity to terahertz waves.

### Fourth Embodiment

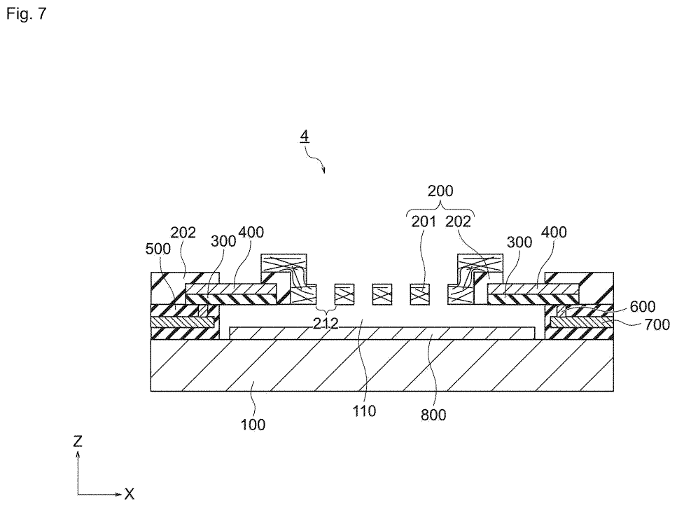

FIG. 7 is a cross-sectional view illustrating a sensor according to a fourth embodiment. Hereinafter, different configurations from those of the sensor 3 described in the third embodiment will be mainly described, and descriptions of similar configurations are omitted.

In a sensor 4 according to the present embodiment, an insulating film 202 is more widely opened than in the sensor 3 according to the third embodiment. A light absorbing film 201 is provided in the opening of the insulating film 202, that is, inside of the insulating film 202. Thus, the sensor 4 has a structure in which the light absorbing film 201 accounts for the major portion of the area of a diaphragm 200.

According to the present embodiment, the thermal capacity of the diaphragm 200 is smaller than that of the third embodiment. Thus, the response speed can be further improved.

### Fifth Embodiment

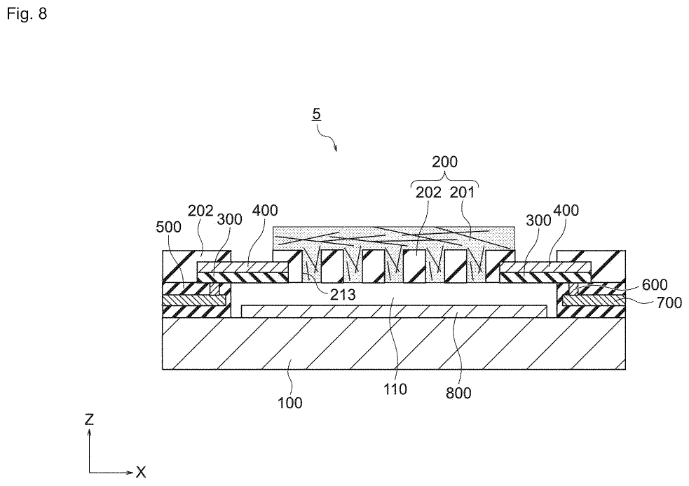

FIG. 8 is a cross-sectional view illustrating a sensor according to a fifth embodiment. Also in the present embodiment, different configurations from those of the sensor 3 described in the third embodiment will be mainly described, and descriptions of similar configurations are omitted.

In a sensor 5 according to the present embodiment, a light absorbing film 201 is a fibrous and porous film. If the light absorbing film 201 is porous, etching gas permeates through the light absorbing film 201 during etching on a part of an insulating film 500 formed as a sacrificial film. Thus, the need for providing etching holes on the light absorbing film 201 is eliminated.

Therefore, in a diaphragm 200 according to the present embodiment, openings 213 are formed only on an insulating film 202 as illustrated in FIG. 8. Moreover, the openings 213 are filled with the light absorbing film 201. Thus, a structure is provided such that the light absorbing film 201 accounts for the major portion of the area of the diaphragm 200.

For this reason, also in the present embodiment, the thermal capacity of the light absorbing film 201 is smaller than that of the third embodiment. Thus, the response speed can be further improved. If the thermal capacity of the light absorbing film 201 per unit volume is smaller than that of the insulating film 202, the thermal capacity of the overall diaphragm 200 is smaller than that of the third embodiment. Moreover, comparing the present embodiment with the fourth embodiment, a reduction in the absorptivity of terahertz waves in the light absorbing film 201 can be eliminated, the reduction being caused by etching holes.

### Sixth Embodiment

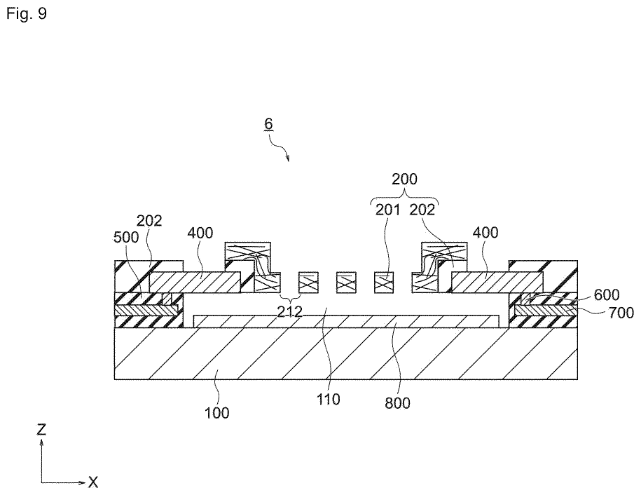

FIG. 9 is a cross-sectional view illustrating a sensor according to a sixth embodiment. Hereinafter, different configurations from those of the sensor 4 described in the fourth embodiment will be mainly described, and descriptions of similar configurations are omitted.

In a sensor 6 according to the present embodiment, a temperature sensing element 400 has the function of a beam portion 300 supporting a diaphragm 200 as well as the function of detecting a temperature.

If the sensor 6 is a thermopile sensor, higher thermal conversion efficiency is obtained by forming the beam portion 300 using a single thermoelectric conversion material than using, for the beam portion 300, a material not contributing to thermoelectric conversion.

Thus, in the present embodiment, the beam portion 300 is made of a thermoelectric conversion material, so that the temperature sensing element 400 also acts as the beam portion 300. This increases thermoelectric conversion efficiency, thereby improving sensitivity to terahertz waves and infrared rays or an SN ratio.

### Seventh Embodiment

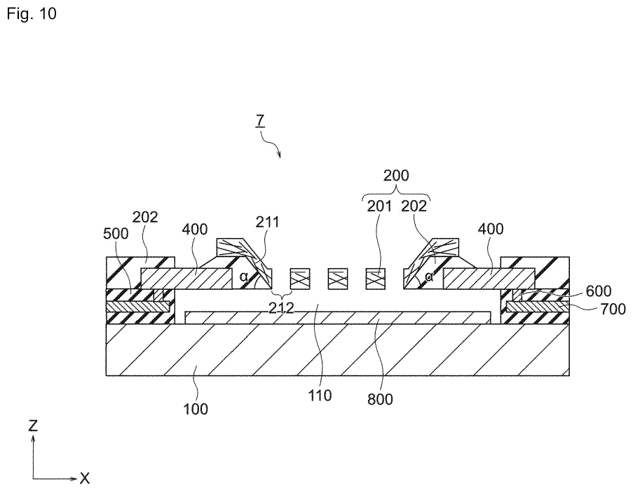

FIG. 10 is a cross-sectional view illustrating a sensor according to a seventh embodiment. Hereinafter, different configurations from those of the sensor 6 described in the sixth embodiment will be mainly described, and descriptions of similar configurations are omitted.

When an insulating film 202 serving as an underlayer of a light absorbing film 201 is formed over one end of a temperature sensing element 400, a step portion is formed on the insulating film 202. In this case, at the step portion, a fibrous material 211 in the light absorbing film 201 is likely to be oriented in Z direction perpendicular to a circuit board 100.

Thus, in the present embodiment, one end of the insulating film 202 in contact with the light absorbing film 201 is formed in a forward tapered shape. In other words, the inner side of the insulating film 202 is tilted such that the opening diameter of the insulating film 202 decreases toward the distal end portion near the circuit board 100. The inner side has a cone angle α as an acute angle. The cone angle is preferably minimized.

According to the present embodiment, one end of the insulating film 202 is formed in a forward tapered shape, so that the fibrous material 211 on one end of the insulating film 202 is hardly oriented in Z direction perpendicular to the circuit board 100. Thus, the orientation of the fibrous material on one end of the insulating film 202 is brought close to a horizontal direction with respect to the circuit board 100, thereby further increasing the response speed.

### Eighth Embodiment

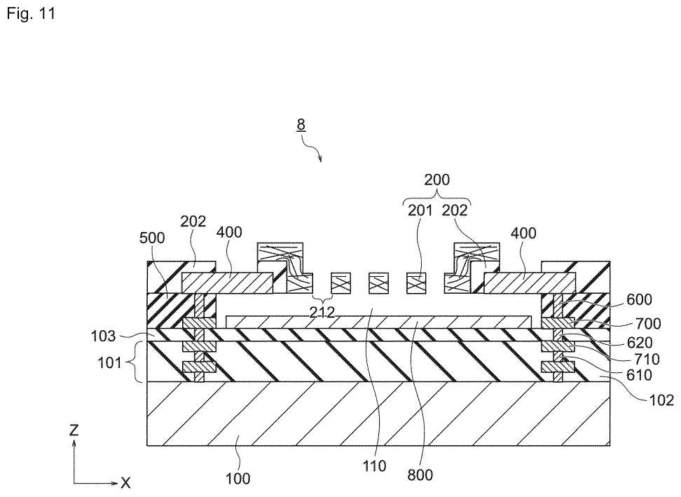

FIG. 11 is a cross-sectional view illustrating a sensor according to an eighth embodiment. Also in the present embodiment, different configurations from those of the sensor 6 described in the sixth embodiment will be mainly described, and descriptions of similar configurations are omitted.

In a sensor 8 illustrated in FIG. 11, a wiring layer 101 is provided on a circuit board 100. Furthermore, an etching stop film 103 is provided on the wiring layer 101. Moreover, a reflective film 800 is provided on the etching stop film 103.

In the wiring layer 101, contact vias 610 and wirings 710 are provided in an interlayer insulating film 102. The interlayer insulating film 102 is, for example, a silicon oxide film. The contact vias 610 and the wirings 710 can be formed by using, for example, metallic materials such as copper (Cu). The contact vias 610 and the wirings 710 are electrically connected to a reading circuit (not illustrated) provided on the circuit board 100.

In the etching stop film 103, contact vias 620 are provided. The etching stop film 103 is, for example, a silicon carbonitride (SiCNₓ) film. The contact vias 620 can be formed by using, for example, metallic materials such as tungsten (W). The contact vias 620 electrically connect wirings 700, which are provided in an insulating film 500, and the wirings 710 provided in the wiring layer 101. In the present embodiment, a temperature sensing element 400 is electrically connected to the reading circuit via the contact vias 620, the contact vias 610 and 620, and the wirings 710.

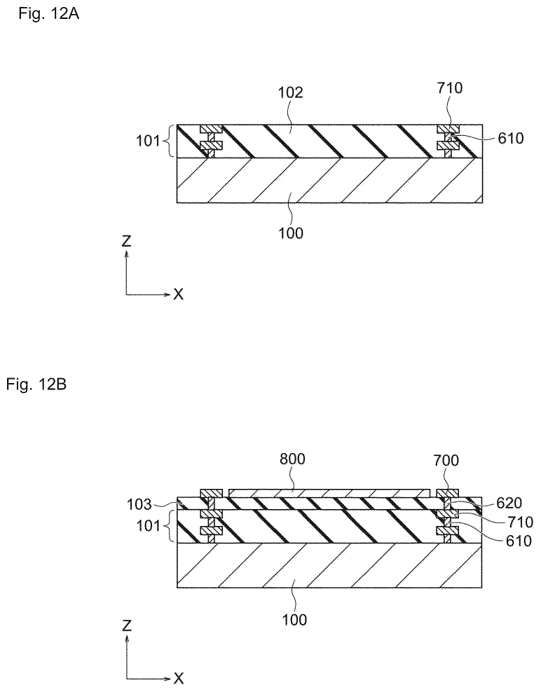

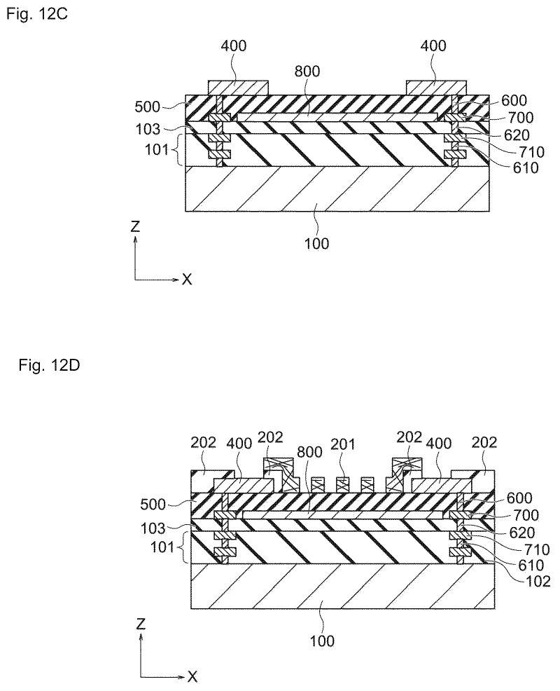

Referring to FIGS. 12A to 12D, an example of a method for manufacturing the sensor 8 according to the present embodiment will be described below.

First, as illustrated in FIG. 12A, the wiring layer 101 is formed on the circuit board 100 on which the reading circuit is formed. At this point, the contact vias 610 and the wirings 710 are formed in the interlayer insulating film 102 by, for example, a dual damascene process.

Thereafter, as illustrated in FIG. 12B, the etching stop film 103, the contact vias 620, a reflective film 800, and the wirings 700 are formed. Specifically, the etching stop film 103 is formed on the wiring layer 101, and then contact holes are formed in the etching stop film 103 by dry etching. Subsequently, the contact vias 620 are formed by filling the contact holes with a metallic material. Thereafter, a metallic film is formed on the top surface of the etching stop film 103 by CVD (Chemical Vapor Deposition). Subsequently, the reflective film 800 and the wirings 700 are simultaneously formed by patterning the metallic film by dry etching.

Thereafter, as illustrated in FIG. 12C, the insulating film 500, the contact vias 600, and the temperature sensing elements 400 are formed. Specifically, the insulating film 500 serving as a sacrificial film is formed on the etching stop film 103. The insulating film 500 is then planarized by CMP (Chemical Mechanical Polishing). Thereafter, contact holes are formed in the insulating film 500 by dry etching. The contact holes are then filled with a metallic material, and an unnecessary metallic film formed on the top surface of the insulating film 500 is removed by CMP, so that the contact vias 600 are formed. Subsequently, a thermoelectric conversion material is formed on the insulating film 500 and is patterned by dry etching, so that the temperature sensing elements 400 are formed.

Thereafter, as illustrated in FIG. 12D, a light absorbing film 201 and an insulating film 202 are formed. Specifically, first, the insulating film 202 is formed on the insulating film 500 by CVD. Thereafter, the insulating film 202 is patterned by dry etching. The light absorbing film 201 is then formed on the patterned insulating film 202 by CVD. At this point, the light absorbing film 201 can be formed also by applying ink, which contains a light absorbing material, onto the insulating film 202. Subsequently, an opening pattern is formed on the light absorbing film 201 by dry etching.

Finally, returning to FIG. 11, a cavity 110 is formed between the reflective film 800 and the light absorbing film 201 by treating the insulating film 500, which serves as a sacrificial layer, by dry etching or wet etching. At this point, the etching stop film 103 has a sufficiently large selection ratio with respect to the insulating film 500, so that etching on the insulating film 500 is stopped at the etching stop film 103. The sensor 8 is not limited to the foregoing manufacturing method and may be manufactured by using other manufacturing processes.

Also in the foregoing embodiment, the sensor having high sensitivity and a high response speed can be provided as in other embodiments.

### Ninth Embodiment

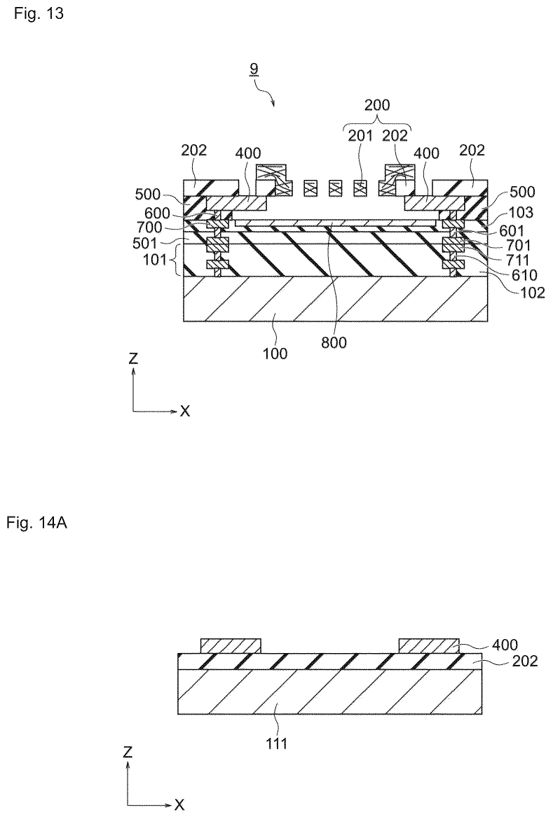

FIG. 13 is a cross-sectional view illustrating a sensor according to a ninth embodiment. Hereinafter, different configurations from those of the sensor 8 in FIG. 11 will be mainly described, and descriptions of similar configurations are omitted.

In a sensor 9 according to the present embodiment, a reading circuit and light detecting portions such as a light absorbing film 201 and temperature sensing elements 400 are manufactured and stacked on different substrates. Moreover, the reading circuit and the temperature sensing element 400 are electrically connected to each other by joining an electrode pad 711 and an electrode pad 701. The electrode pad 711 is provided near a circuit board 100 provided with the reading circuit. The electrode pad 701 is provided near a treated substrate (not illustrated in FIG. 13) provided with the temperature sensing element 400.

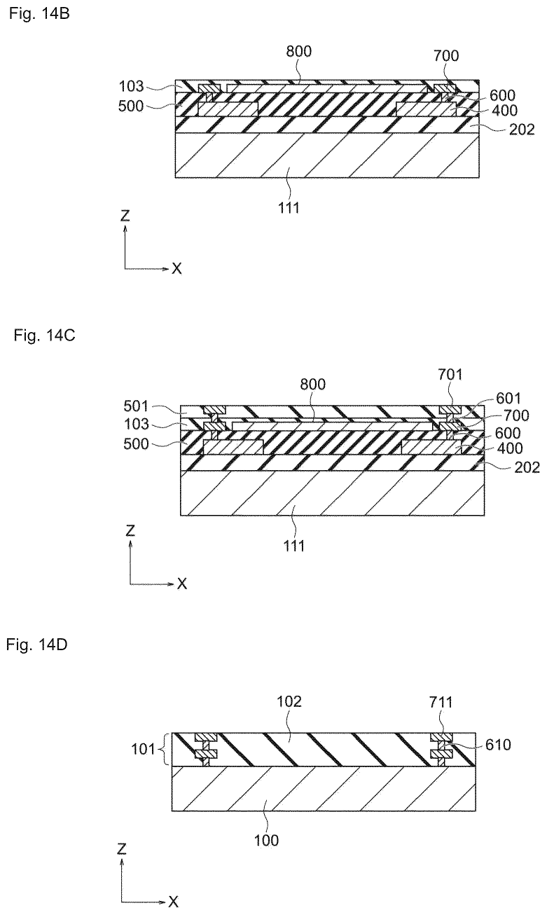

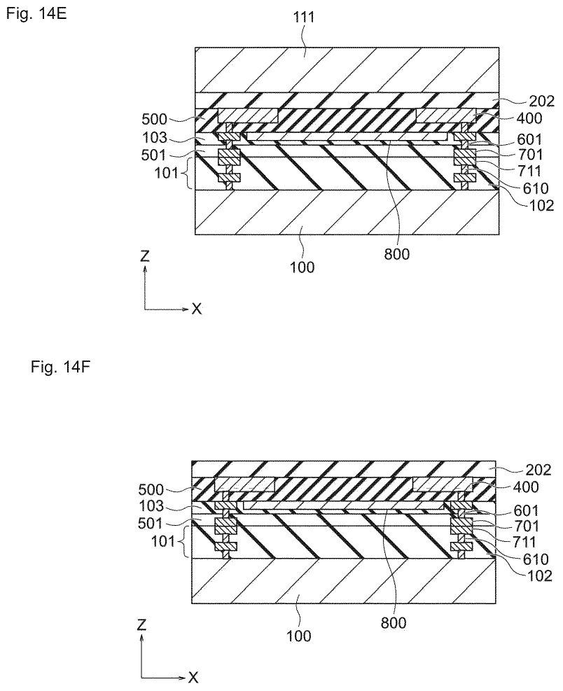

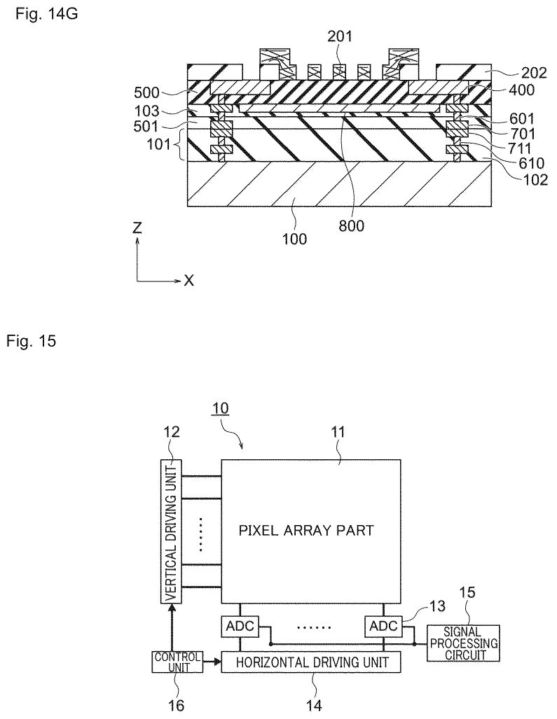

Referring to FIGS. 14A to 14G, an example of a method for manufacturing the sensor 9 according to the present embodiment will be described below.

First, as illustrated in FIG. 14A, an insulating film 202 and the temperature sensing elements 400 are formed. Specifically, the insulating film 202 is formed on a treated substrate 111. The treated substrate 111 is, for example, a silicon substrate. Subsequently, the temperature sensing elements 400 are formed on the insulating film 202. The temperature sensing elements 400 are patterned by dry etching.

Thereafter, as illustrated in FIG. 14B, the insulating film 500, contact vias 600, wirings 700, a reflective film 800, and an etching stop film 103 are formed. Specifically, the insulating film 500 serving as a sacrificial film is formed on the insulating film 202. Subsequently, the insulating film 500 is planarized by CMP. Thereafter, etching holes are formed in the insulating film 500. The contact vias 600 are formed by filling the etching holes with a metallic material. A metallic film is then formed on the top surface of the insulating film 500 by CVD. Subsequently, the reflective film 800 and the wirings 700 are simultaneously formed by patterning the metallic film by dry etching. Thereafter, the etching stop film 103 is formed on the insulating film 500 so as to cover the reflective film 800 and the wirings 700. The formed etching stop film 103 is planarized by CMP.

Thereafter, as illustrated in FIG. 14C, an interlayer insulating film 501, contact vias 601, and the electrode pad 701 are formed. The interlayer insulating film 501 is formed on the etching stop film 103. The interlayer insulating film 501 is, for example, a silicon oxide film. The contact vias 601 and the electrode pad 701 are formed in the interlayer insulating film 501 by, for example, a dual damascene process.

Subsequently, as illustrated in FIG. 14D, a wiring layer 101 is formed on the circuit board 100 on which the reading circuit is formed. At this point, the contact vias 610 and the electrode pad 711 are formed in the interlayer insulating film 102 by, for example, the dual damascene process.

Subsequently, as illustrated in FIG. 14E, the circuit board 100 and the treated substrate 111 are joined to each other. Specifically, the treated substrate 111 is inverted to be stacked on the circuit board 100 such that the electrode pad 711 and the electrode pad 701 are joined to each other. By joining the electrode pad 711 and the electrode pad 701, the temperature sensing elements 400 are electrically connected to the reading circuit.

Subsequently, as illustrated in FIG. 14F, the treated substrate 111 is removed by, for example, polishing.

Thereafter, as illustrated in FIG. 14G, the light absorbing film 201 is formed. Specifically, the insulating film 202 is patterned by dry etching. The light absorbing film 201 is then formed on the patterned insulating film 202 and on the insulating film 500 exposed by patterning the insulating film 202. As in the eighth embodiment, the light absorbing film 201 can be formed by CVD or applying ink containing a light absorbing material. The light absorbing film 201 is patterned by dry etching.

Finally, returning to FIG. 13, a cavity 110 is formed between the reflective film 800 and the light absorbing film 201 by treating the insulating film 500, which serves as a sacrificial layer, by dry etching or wet etching. At this point, the etching stop film 103 has a sufficiently large selection ratio with respect to the insulating film 500, so that etching on the insulating film 500 is stopped at the etching stop film 103.

Also in the foregoing embodiment, the sensor having high sensitivity and a high response speed can be provided as in other embodiments. In the present embodiment, the reading circuit is formed on the circuit board 100, whereas the insulating film 202 and the temperature sensing elements 400 are formed on the treated substrate 111 different from the circuit board 100. Thus, even if the insulating film 202 and the temperature sensing elements 400 are formed at high film-forming temperatures, the circuit board 100 is not thermally damaged.

Furthermore, the circuit board 100 disposed immediately below the temperature sensing elements 400 as in the present embodiment facilitates routing of wiring in an imaging device including the plurality of sensors 9 arranged in a two-dimensional array. The sensor 9 is not limited to the foregoing manufacturing method and may be manufactured by using other manufacturing processes.

### Tenth Embodiment

FIG. 15 is a block diagram illustrating the configuration of an imaging device according to a tenth embodiment. The imaging device 10 in FIG. 15 includes a pixel array part 11, a vertical driving unit 12, an ADC (Analog Digital Converter) 13, a horizontal driving unit 14, a signal processing circuit 15, and a control unit 16.

In the pixel array part 11, a plurality of pixels are arranged in a two-dimensional array. The specific configuration of the pixel array part 11 will be described later.

The vertical driving unit 12 is connected to the row reset line (not illustrated) and the row selection line (not illustrated) of the pixel array part 11. The vertical driving unit 12 includes a shift register and an address decoder and controls scanning of the pixel rows and the addresses of the pixel rows when selecting the pixels of the pixel array part 11.

The ADC 13 is provided according to the pixel columns of the pixel array part 11. The ADC 13 converts an analog pixel signal output from each pixel into a digital pixel signal. For the ADC 13, for example, a single-slope ADC is applicable. The single-slope ADC compares an analog pixel signal read from each signal and a ramp-wave reference signal, and then converts the analog pixel signal into a digital signal with an amplified difference.

The horizontal driving unit 14 includes a shift register and an address decoder and controls scanning of pixel columns and the addresses of the pixel columns when reading the pixel signal from the pixel array part 11. Under the control of the horizontal driving unit 14, the pixel signal converted into a digital signal by the ADC 13 is read by the signal processing circuit 15.

The signal processing circuit 15 performs predetermined signal processing on the digital signal read from the ADC 13 and generates two-dimensional image data. For example, the signal processing circuit 15 performs digital signal processing such as parallel-to-serial conversion, compression, encoding, addition, averaging, and intermittent operation.

The control unit 16 controls the vertical driving unit 12 and the horizontal driving unit 14.

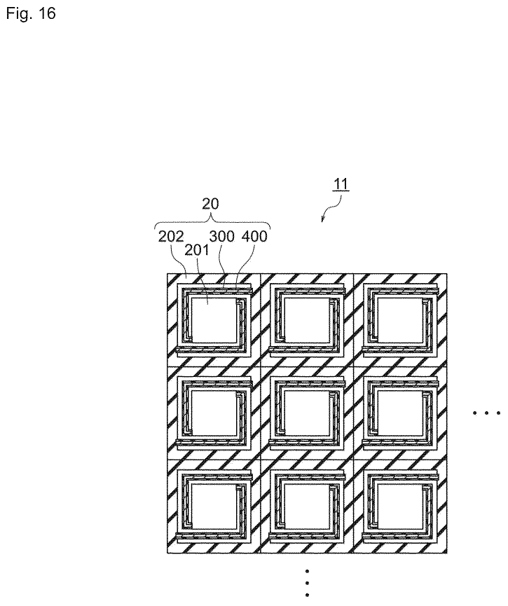

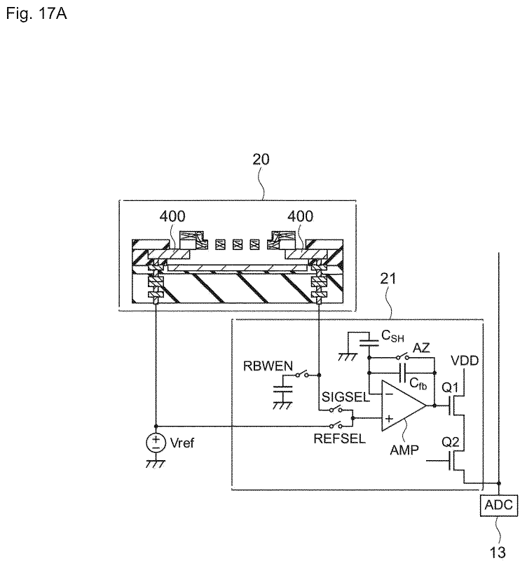

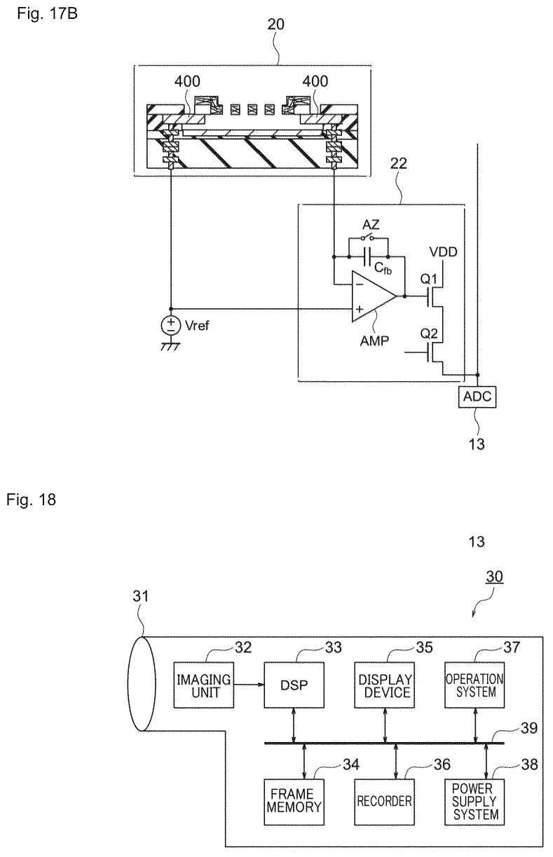

FIG. 16 is a plan view of the pixel array part 11. As illustrated in FIG. 16, the pixel array part 11 includes a plurality of sensors 20 arranged in a two-dimensional array. The sensor 20 is one of the sensors 1 to 9 described in the first to ninth embodiments. A pixel includes the sensor 20 and a single reading circuit. Referring to FIGS. 17A and 17B, an example of the reading circuit will be described below.

FIG. 17A is a circuit diagram illustrating a reading circuit of a voltage reading system. In a reading circuit 21 of FIG. 17A, the detected voltage of the temperature sensing element 400 is input to the noninverting input terminal (+) of a differential amplifier AMP through a first selector switch REFSEL or a second selector switch SIGSEL. At this point, the potential of the first selector switch REFSEL is set at a reference voltage Vrerf. Moreover, a bandwidth-shaping capacitor RBWEN for limiting a signal band is connected to a transmission line from the sensor 20 to the second selector switch SIGSEL.

To the inverting input terminal (−) of the differential amplifier AMP, a sample hold capacitor C_{SH} is connected. Moreover, at the differential amplifier AMP, an auto zero switch AZ for resetting the potential of the inverting input terminal (−) and a feedback capacitor C_{fb} are connected in parallel between the inverting input terminal (−) and the output terminal. The auto zero switch AZ is turned on and off under the control of the vertical driving unit 12.

The output terminal of the differential amplifier AMP is connected to the gate of an amplifier transistor Q1. The drain of the amplifier transistor Q1 is set at a power supply voltage VDD. The source of the amplifier transistor Q1 is connected to the drain of a selection transistor Q2. The source of the selection transistor Q2 is connected to the ADC 13. The selection transistor Q2 is turned on and off on the basis of a control signal inputted from the vertical driving unit 12 to the gate.

In the reading circuit 21 configured thus, when the selection transistor Q2 is turned on, the output signal of the differential amplifier AMP is amplified by the amplifier transistor Q1 and is read as a pixel signal by the ADC 13.

FIG. 17B is a circuit diagram illustrating a reading circuit of a CTIA (Capacitive Transimpedance Amplifier) system. In FIG. 17B, the same circuit elements as those of the reading circuit 21 in FIG. 17A are denoted by the same reference numerals, and detailed descriptions thereof are omitted.

In a reading circuit 22 in FIG. 17B, the detected voltage of the temperature sensing element 400 is input to the noninverting input terminal (+) and the inverting input terminal (−) of the differential amplifier AMP. At this point, the potential of the noninverting input terminal (+) is set at the reference voltage Vrerf. Moreover, at the differential amplifier AMP, the auto zero switch AZ and the feedback capacitor C_{fb} are connected in parallel between the inverting input terminal (−) and the output terminal.

Moreover, the amplifier transistor Q1 is connected to the output terminal of the differential amplifier AMP as in the reading circuit 21, and the amplifier transistor Q1 is connected in series with the selection transistor Q2.

Also in the reading circuit 22 configured thus, when the selection transistor Q2 is turned on, the output signal of the differential amplifier AMP is amplified by the amplifier transistor Q1 and is read as a pixel signal by the ADC 13 as in the reading circuit 21.

According to the present embodiment, high pixel sensitivity is obtained with a high response speed, thereby improving imaging capability.

### Eleventh Embodiment

In the following description, the imaging device 10 is applied to an electronic device such as an infrared camera.

FIG. 18 is a block diagram illustrating a configuration example of an electronic apparatus according to an eleventh embodiment.

As illustrated in FIG. 18, an electronic device 30 according to the present example includes an imaging optical system 31 including lenses, an imaging unit 32, a DSP (Digital Signal Processor) circuit 33, a frame memory 34, a display device 35, a recorder 36, an operation system 37, and a power supply system 38. In addition, the DSP circuit 33, the frame memory 34, the display device 35, the recorder 36, the operation system 37, and the power supply system 38 are connected to one another via a bus line 39.

The imaging optical system 31 captures incident light (image light) from a subject and forms an image on the imaging surface of the imaging unit 32. The imaging unit 32 converts an amount of incident light, which forms an image on the imaging surface by the imaging optical system 31, into an electrical signal for each pixel and outputs the electrical signal as a pixel signal. The DSP circuit 33 performs typical camera signal processing, for example, white balance processing, demosaicing, or gamma correction.

The frame memory 34 is used to store data as appropriate in the process of signal processing in the DSP circuit 33. The display device 35 includes a panel display device such as a liquid crystal display device or an organic EL (electro luminescence) display device, and displays a moving image or a still image captured by the imaging unit 32. The recorder 36 records a moving image or a still image captured by the imaging unit 32 on a recording medium such as a portable semiconductor memory, an optical disk, or an HDD (Hard Disk Drive).

The operation system 37 issues operation commands for various functions of the electronic device 30 in response to user operations. The power supply system 38 supplies, as appropriate, various power supplies serving as operation power supplies for the DSP circuit 33, the frame memory 34, the display device 35, the recorder 36, and the operation system 37 to the targets of supply.

In the electronic device 30 configured thus, the imaging device 10 according to the tenth embodiment may be used as the imaging unit 32. The imaging device 10 according to the first embodiment includes one of the sensors 1 to 9 described in the first to ninth embodiments. Therefore, the imaging capability can be improved by applying the imaging device 10 to the imaging unit 32.

### <Application to Mobile Object>

The technique of the present disclosure (the present technique) can be applied to various products. For example, the technique according to the present disclosure may be implemented as a device mounted on any type of mobile object such as an automobile, an electric automobile, a hybrid electric automobile, a motorcycle, a bicycle, a personal mobility device, an airplane, a drone, a ship, or a robot.

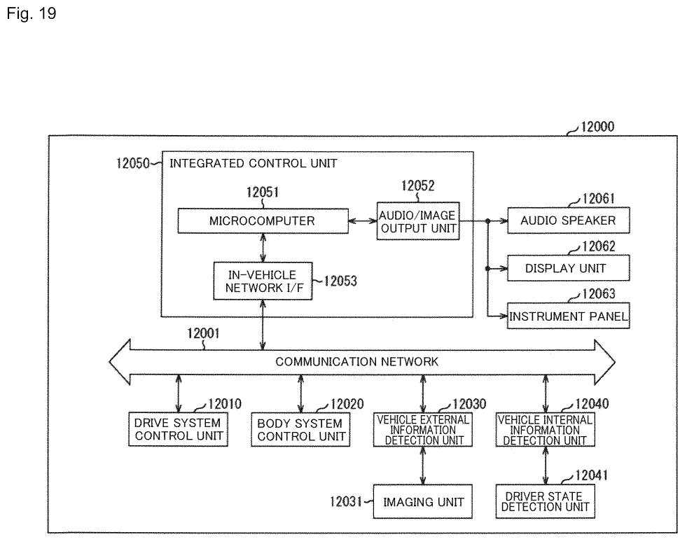

FIG. 19 is a block diagram illustrating a schematic configuration example of a vehicle control system, which is an example of a mobile object control system to which the technique according to the present disclosure can be applied.

A vehicle control system 12000 includes a plurality of electronic control units connected via a communication network 12001. In the example illustrated in FIG. 19, the vehicle control system 12000 includes a drive system control unit 12010, a body system control unit 12020, a vehicle external information detection unit 12030, a vehicle internal information detection unit 12040, and an integrated control unit 12050. In addition, as the functional configuration of the integrated control unit 12050, a microcomputer 12051, an audio/image output unit 12052, and an in-vehicle network interface (I/F) 12053 are illustrated.

The drive system control unit 12010 controls an operation of an apparatus related to a drive system of a vehicle according to various programs. For example, the drive system control unit 12010 functions as a control device for a driving force generation device that generates a driving force of a vehicle, e.g., an internal combustion engine or a driving motor, a driving force transmission mechanism that transmits a driving force to wheels, a steering mechanism that adjusts a steering angle of a vehicle, and a braking device that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle external information detection unit 12030 detects information on the outside of the vehicle in which the vehicle control system 12000 is mounted. For example, an imaging unit 12031 is connected to the vehicle external information detection unit 12030. The vehicle external information detection unit 12030 causes the imaging unit 12031 to capture an image of the outside of the vehicle and receives the captured image. The vehicle external information detection unit 12030 may perform object detection processing or distance detection processing for persons, cars, obstacles, signs, and letters on the road on the basis of the received image.

The imaging unit 12031 is a sensor that receives light and outputs an electrical signal according to the amount of the received light. The imaging unit 12031 can also output the electrical signal as an image or distance measurement information. In addition, the light received by the imaging unit 12031 may be visible light or invisible light such as infrared light.

The vehicle internal information detection unit 12040 detects information on the inside of the vehicle. For example, a driver state detection unit 12041 that detects a driver's state is connected to the vehicle internal information detection unit 12040. The driver state detection unit 12041 includes, for example, a camera that captures an image of a driver, and the vehicle internal information detection unit 12040 may calculate a degree of fatigue or concentration of the driver or may determine whether or not the driver is dozing on the basis of detection information input from the driver state detection unit 12041.

The microcomputer 12051 can calculate control target values for the driving force generation device, the steering mechanism, or the braking device on the basis of information on the inside and outside of the vehicle, the information being acquired by the vehicle external information detection unit 12030 or the vehicle internal information detection unit 12040, and the microcomputer 12051 can output control commands to the drive system control unit 12010. For example, the microcomputer 12051 can perform cooperative control for the purpose of implementing the functions of an advanced driver assistance system (ADAS) including vehicle collision avoidance, impact mitigation, following traveling based on an inter-vehicle distance, vehicle speed maintenance driving, vehicle collision warning, or vehicle lane deviation warning.

Furthermore, the microcomputer 12051 can perform cooperative control for the purpose of automated driving or the like in which autonomous travel is performed without depending on operations of the driver, by controlling the driving force generator, the steering mechanism, or the braking device or the like on the basis of information about the surroundings of the vehicle, the information being acquired by the vehicle external information detection unit 12030 or the vehicle internal information detection unit 12040.

In addition, the microcomputer 12051 can output a control command to the body system control unit 12030 on the basis of the information on the outside of the vehicle, the information being acquired by the vehicle external information detection unit 12030. For example, the microcomputer 12051 can perform coordinated control for the purpose of antiglare such as switching a high beam to a low beam by controlling a headlamp according to a position of a vehicle ahead or an oncoming vehicle detected by the vehicle external information detection unit 12030.

The audio/image output unit 12052 transmits an output signal of at least one of an audio and an image to an output device capable of visually or auditorily providing a notification about information to a passenger of the vehicle or the outside of the vehicle. In the example of FIG. 19, an audio speaker 12061, a display unit 12062, and an instrument panel 12063 are exemplified as output devices. The display unit 12062 may include, for example, at least one of an onboard display and a head-up display.

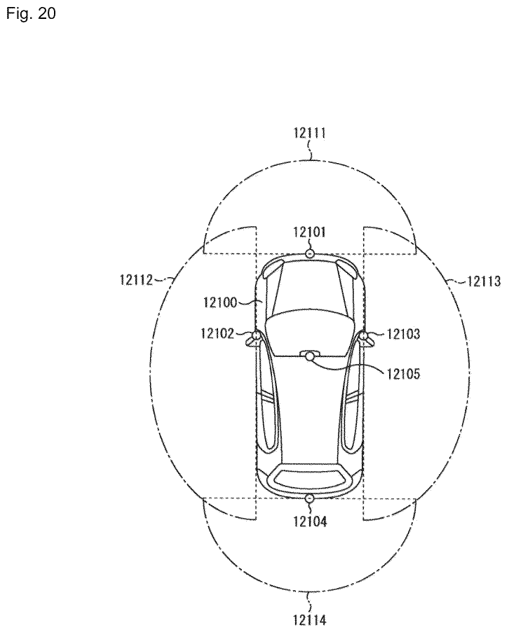

FIG. 20 illustrates an example of the installation position of the imaging unit 12031.

In FIG. 20, the imaging unit 12031 includes imaging units 12101, 12102, 12103, 12104, and 12105.

The imaging units 12101, 12102, 12103, 12104, and 12105 are provided at, for example, the positions of a front nose, side mirrors, a rear bumper, a back door, an internal upper portion of the front windshield of the vehicle 12100. The imaging unit 12101 provided at the front nose and the imaging unit 12105 provided at the internal upper portion of the front windshield mainly acquire images ahead of the vehicle 12100. The imaging units 12102 and 12103 provided at the side mirrors mainly acquire images on lateral sides of the vehicle 12100. The imaging unit 12104 provided at the rear bumper or the back door mainly acquires an image behind the vehicle 12100. The imaging unit 12105 provided at the upper portion of the windshield inside of the vehicle is mainly used for detection of a vehicle ahead, a pedestrian, an obstacle, a traffic signal, a traffic sign, or a lane or the like.

FIG. 20 illustrates an example of the imaging ranges of the imaging units 12101 to 12104. An imaging range 12111 indicates the imaging range of the imaging unit 12101 provided at the front nose, an imaging range 1211212113 indicating the imaging ranges of the imaging units 12102 and 12103 provided at the side mirrors, and an imaging range 12114 indicates the imaging range of the imaging unit 12104 provided at the rear bumper or the back door. For example, a bird's-eye view image of the vehicle 12100 as viewed from above can be obtained by superimposing pieces of image data captured by the imaging units 12101 to 12104.

At least one of the imaging units 12101 to 12104 may have the function of obtaining distance information. For example, at least one of the imaging units 12101 to 12104 may be a stereo camera including a plurality of imaging elements or may be an imaging element that has pixels for phase difference detection.

For example, the microcomputer 12051 can extract, particularly, a closest three-dimensional object on a traveling path of the vehicle 12100 as a three-dimensional object traveling at a predetermined speed (for example, 0 km/h or higher) in the substantially same direction as the vehicle 12100, as a vehicle ahead by obtaining a distance to each three-dimensional object in the imaging ranges 12111 to 12114 and a temporal change in the distance (a relative speed with respect to the vehicle 12100) on the basis of distance information obtained from the imaging units 12101 to 12104. The microcomputer 12051 can also set a distance to a vehicle ahead in advance and perform automatic brake control (including following stop control) and automatic acceleration control (including following start control). Therefore, coordinated control can be performed for the purpose of, for example, automated driving in which the vehicle travels in an automated manner without the need for the operations of a driver.

For example, the microcomputer 12051 can classify three-dimensional data on three-dimensional objects into two-wheeled vehicles, normal vehicles, large vehicles, pedestrians, and other three-dimensional objects such as electric poles and extract the data on the basis of distance information obtained from the imaging units 12101 to 12104. The three-dimensional data can be used for automated avoidance of obstacles. For example, the microcomputer 12051 differentiates surrounding obstacles of the vehicle 12100 into obstacles that can be viewed by the driver of the vehicle 12100 and obstacles that are difficult to view. Thereafter, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display unit 12062, and forced deceleration or avoidance steering is performed through the drive system control unit 12010, thereby providing driving support for collision avoidance.

At least one of the imaging units 12101 to 12104 may be an infrared camera that detects infrared rays. For example, the microcomputer 12051 can recognize a pedestrian by determining the presence or absence of a pedestrian in images captured by the imaging units 12101 to 12104. A pedestrian is recognized by, for example, the step of extracting feature points in the captured images of the imaging units 12101 to 12104 acting as infrared cameras and the step of performing pattern matching on a series of feature points indicating an outline of an object to determine whether or not the object is a pedestrian. When the microcomputer 12051 determines that a pedestrian is present in the captured images of the imaging units 12101 to 12104 and recognizes the pedestrian, the audio/image output unit 12052 controls the display unit 12062 such that a square contour line for emphasis is superimposed and displayed with the recognized pedestrian. In addition, the audio/image output unit 12052 may control the display unit 12062 such that an icon indicating a pedestrian or the like is displayed at a desired position.

An example of the vehicle control system to which the technique according to the present disclosure can be applied has been described above. The technique according to the present disclosure is applicable to, for example, the imaging unit 12031 among the configurations described above. Specifically, the imaging unit 32 can be applied to the imaging unit 12031. By applying the technique according to the present disclosure, a captured image can be obtained with higher sensitivity and a high response speed and thus the safety can be improved.

The present technique can also be configured as follows:
(1) A sensor including: a substrate;
a diaphragm including a light absorbing film disposed with a cavity interposed between the light absorbing film and the substrate;
a beam portion that supports the diaphragm on the substrate; and
a temperature sensing element that detects a temperature change of the light absorbing film,
wherein the light absorbing film contains a fibrous material or a sheet-like material that absorbs terahertz waves or infrared rays, and
the mean value of angles formed by the direction of the fibrous material or the planar direction of a sheet and a direction parallel to the substrate is 45° or less at least in a part of the region of the light absorbing film.
(2) A sensor including: a substrate;
a diaphragm including a light absorbing film disposed with a cavity interposed between the light absorbing film and the substrate;
a beam portion that supports the diaphragm on the substrate; and
a temperature sensing element that detects a temperature change of the light absorbing film,
wherein the light absorbing film contains a material that absorbs terahertz waves or infrared rays, and
thermal conductivity in a direction parallel to the substrate is higher than thermal conductivity in a direction perpendicular to the substrate at least in a part of the region of the light absorbing film.
(3) A sensor including: a substrate;
a diaphragm including a light absorbing film disposed with a cavity interposed between the light absorbing film and the substrate;
a beam portion that supports the diaphragm on the substrate; and
a temperature sensing element that detects a temperature change of the light absorbing film,
wherein the light absorbing film contains a material that absorbs terahertz waves or infrared rays, and
the light absorbing film has an opening, the opening having a diameter set at a half or less of a wavelength of light to be detected.
(4) The sensor according to any one of (1) to (3), wherein when the light absorbing film is viewed from a light receiving surface that receives the terahertz waves or the infrared rays, the fibrous material is oriented in one direction.
(5) The sensor according to any one of (1) to (3), wherein when the light absorbing film is viewed from a light receiving surface that receives the terahertz waves or the infrared rays, the fibrous material is randomly oriented.
(6) The sensor according to any one of (1) to (3), wherein when the light absorbing film is a laminated film of layers containing the fibrous material oriented in one direction, the layers having different fiber directions in the laminated film.
(7) The sensor according to any one of (1) to (3), wherein the diaphragm further includes an insulating film provided between the light absorbing film and the temperature sensing element, and
the light absorbing film is provided inside of the insulating film.
(8) The sensor according to any one of (1) to (3), wherein the light absorbing film is a fibrous or sheet-like and porous film.
(9) The sensor according to any one of (1) to (8), wherein the temperature sensing element also acts as the beam portion.
(10) The sensor according to any one of (1) to (9), wherein the diaphragm further includes an insulating film provided under the light absorbing film, and
the insulating film in contact with the temperature sensing element has one end formed in a forward tapered shape.
(11) The sensor according to any one of (1) to (10), further including a reflective film that is provided on the underside of the diaphragm or the front side of the substrate opposed to the diaphragm with the cavity interposed between the substrate and the diaphragm, the reflective film reflecting at least the terahertz waves or the infrared rays.
(12) The sensor according to any one of (1) to (11), wherein the temperature sensing element is connected via a contact via and a wiring to a reading circuit provided on the substrate.
(13) An imaging device in which the sensors according to any one of (1) to (12) are arranged in a two-dimensional array.
(14) An electronic device including the imaging device according to (13).

### REFERENCE SIGNS LIST

1-9, 20 Sensor
10 Imaging device
21, 22 Reading circuit
30 Electronic device
600 Contact via
700 Wiring
100 Circuit board
110 Cavity
200 Diaphragm
200a Light receiving surface
201 Light absorbing film
202 Insulating film
212 Opening
300 Beam portion
400 Temperature sensing element
800 Reflective film

1. A sensor comprising: a substrate;
a diaphragm including a light absorbing film disposed with a cavity interposed between the light absorbing film and the substrate;
a beam portion that supports the diaphragm on the substrate; and
a temperature sensing element that detects a temperature change of the light absorbing film,
wherein the light absorbing film contains a fibrous material or a sheet-like material that absorbs terahertz waves or infrared rays, and
the mean value of angles formed by a direction of the fibrous material or a planar direction of a sheet and a direction parallel to the substrate is 45° or less at least in a part of a region of the light absorbing film.

2. A sensor comprising: a substrate;
a diaphragm including a light absorbing film disposed with a cavity interposed between the light absorbing film and the substrate;
a beam portion that supports the diaphragm on the substrate; and
a temperature sensing element that detects a temperature change of the light absorbing film,
wherein the light absorbing film contains a material that absorbs terahertz waves or infrared rays, and
thermal conductivity in a direction parallel to the substrate is higher than thermal conductivity in a direction perpendicular to the substrate at least in a part of a region of the light absorbing film.

3. A sensor comprising: a substrate;
a diaphragm including a light absorbing film disposed with a cavity interposed between the light absorbing film and the substrate;
a beam portion that supports the diaphragm on the substrate; and
a temperature sensing element that detects a temperature change of the light absorbing film,
wherein the light absorbing film contains a material that absorbs terahertz waves or infrared rays, and
the light absorbing film has an opening, the opening having a diameter set at a half or less of a wavelength of light to be detected.

4. The sensor according to claim 1, wherein when the light absorbing film is viewed from a light receiving surface that receives the terahertz waves or the infrared rays, the fibrous material is oriented in one direction.

5. The sensor according to claim 1, wherein when the light absorbing film is viewed from a light receiving surface that receives the terahertz waves or the infrared rays, the fibrous material is randomly oriented.

6. The sensor according to claim 1, wherein when the light absorbing film is a laminated film of layers containing the fibrous material oriented in one direction, the layers having different fiber directions in the laminated film.

7. The sensor according to claim 3, wherein the diaphragm further includes an insulating film provided between the light absorbing film and the temperature sensing element, and
the light absorbing film is provided inside of the insulating film.

8. The sensor according to claim 1, wherein the light absorbing film is a fibrous or sheet-like and porous film.

9. The sensor according to claim 1, wherein the temperature sensing element also acts as the beam portion.

10. The sensor according to claim 1, wherein the diaphragm further includes an insulating film provided under the light absorbing film, and
the insulating film in contact with the temperature sensing element has one end formed in a forward tapered shape.

11. The sensor according to claim 1, further comprising a reflective film that is provided on an underside of the diaphragm or a front side of the substrate opposed to the diaphragm with the cavity interposed between the substrate and the diaphragm, the reflective film reflecting at least the terahertz waves or the infrared rays.

12. The sensor according to claim 1, wherein the temperature sensing element is connected via a contact via and a wiring to a reading circuit provided on the substrate.

13. An imaging device in which the sensor according to claim 3 is arranged with a two-dimensional array.

14. An electronic device comprising the imaging device according to claim 13.
